(19) United States
(12) Patent Application Publication
(10) Pub. No.: US 2024/0405042 A1
(43) Pub. Date: Dec. 5, 2024

(54) OPTICAL DETECTION MODULE AND RELATED MANUFACTURING METHOD

(71) Applicant: PixArt Imaging Inc., Hsin-Chu City (TW)

(72) Inventors: Jen-Chuan Chen, Hsin-Chu City (TW); Chi-Chih Shen, Hsin-Chu City (TW); Hsuan-Yao Chang, Hsin-Chu City (TW); Yu-Chiao Peng, Hsin-Chu City (TW)

(73) Assignee: PixArt Imaging Inc., Hsin-Chu City (TW)

(21) Appl. No.: 18/204,959

(22) Filed: Jun. 2, 2023

(51) Int. Cl. H01L 27/146; H01L 31/18

(52) U.S. Cl. CPC H01L 27/14618; H01L 27/14683; H01L 31/1892

(57) ABSTRACT

An optical detection module and a related manufacturing method are applied for chip scale package technology. The optical detection module includes a chip scale package assembly and a light sheltering layer. The chip scale package assembly includes a glass substrate, a detection chip, an isolation layer, a plurality of redistribution layers, and a plurality of conductive contacts. The detection chip is located above the glass substrate. The isolation layer is disposed on a surface of the detection chip opposite to the glass substrate. The plurality of redistribution layers is disposed on the isolation layer and spaced from each other, and having a plurality of conductive units. The plurality of conductive contacts is respectively disposed on the plurality of conductive units. The light sheltering layer is disposed on a lateral surface of the chip scale package assembly, and adapted to block light transmission and provide a covering protection function.

### BACKGROUND OF THE INVENTION

### 1. Field of the Invention

The present invention relates to an optical detection module and a related manufacturing method, and more particularly, to an optical detection module with the anti-light leakage function and a related manufacturing method.

### 2. Description of the Prior Art

A conventional chip scale package assembly disposes the detection chip on the glass substrate, and faces the imaging area of the detection chip toward the glass substrate to form the optical detection module. Two opposite surfaces of the glass substrate respectively are the light receiving area and the installation area of the detection chip. However, the conventional optical detection module made by chip scale package technology may easily have inaccurate noises, which results from the ambient light passing through the lateral surface of the glass substrate. The imaging area of the detection chip may not distinguish the optical detection signal from the ambient light, so that the detection result of the optical detection module is inaccurate due to interference of the ambient light. Therefore, design of a chip scale package assembly applied for the chip scale package technology and capable of preventing interference from the ambient light is an important issue in the optical detection industry.

### SUMMARY OF THE INVENTION

The present invention provides an optical detection module with the anti-light leakage function and a related manufacturing method for solving above drawbacks.

According to the claimed invention, a manufacturing method applied for chip scale package technology includes disposing a plurality of chip scale package assemblies spaced from each other on a carrier, filling light sheltering material into a gap formed between two adjacent chip scale package assemblies of the plurality of chip scale package assemblies, removing the carrier, and trimming the light sheltering material in the middle to form two light sheltering layers attached to the two adjacent chip scale package assemblies respectively, so that the two adjacent chip scale package assemblies with its own light sheltering layers respectively are separated to set as two optical detection modules. Each of the two light sheltering layers is attached to a lateral surface of a glass substrate of each of the two adjacent chip scale package assemblies.

According to the claimed invention, the chip scale package assembly includes a chip scale package detector, and each of the two light sheltering layers is attached to a lateral surface of a glass substrate of each of two adjacent chip scale package detectors. The manufacturing method further includes attaching the light sheltering layer to a lateral surface of a wafer level lens, and assembling the wafer level lens having the light sheltering layer with the chip scale package detector. Besides, the chip scale package assembly includes a chip scale package detector and a wafer level lens, the light sheltering layer is attached to a lateral surface of a glass substrate of each of two adjacent chip scale package detectors, and further attached to a lateral surface of each of two adjacent wafer level lenses.

According to the claimed invention, the manufacturing method further includes arranging the plurality of chip scale package assemblies on the carrier at a distance of 5˜500 micrometers from each other. The manufacturing method further includes filling the light sheltering material between the glass substrates of the two adjacent chip scale package assemblies, and a filling height of the light sheltering material is equal to or greater than as a thickness of the glass substrate of the chip scale package assembly. The manufacturing method further includes trimming the light sheltering material in the middle that is set between the two adjacent chip scale package assemblies to form the two light sheltering layers respectively having a thickness of 5˜500 micrometers. An optical density of the light sheltering layer of the optical detection module is ranged between 1˜5.

According to the claimed invention, a manufacturing method applied for chip scale package technology includes disposing a plurality of chip scale package assemblies without conductive contacts spaced from each other on a carrier, disposing a sheltering layer on conductive units of the plurality of chip scale package assemblies, filling light sheltering material into a gap formed between two adjacent chip scale package assemblies of the plurality of chip scale package assemblies, removing the sheltering layer to dispose the conductive contacts respectively on the conductive units, removing the carrier, and trimming the light sheltering material in the middle to form two light sheltering layers attached to the two adjacent chip scale package assemblies respectively, so that the two adjacent chip scale package assemblies with its own light sheltering layers respectively are separated to set as two optical detection modules.

According to the claimed invention, the manufacturing method further includes arranging the plurality of chip scale package assemblies on the carrier at a distance of 5˜500 micrometers from each other. The manufacturing method further includes filling the light sheltering material between glass substrates of the two adjacent chip scale package assemblies, and a filling height of the light sheltering material is equal to or greater than a projection height of the conductive units relative to the carrier. The manufacturing method further includes trimming the light sheltering material in the middle that is set between the two adjacent chip scale package assemblies to form the two light sheltering layers respectively having a thickness of 5˜500 micrometers. An optical density of the light sheltering layer of the optical detection module is ranged between 1˜5.

According to the claimed invention, an optical detection module applied for chip scale package technology includes a chip scale package assembly and a light sheltering layer. The chip scale package assembly includes a glass substrate, a detection chip, an isolation layer, a plurality of redistribution layers, and a plurality of conductive contacts. The detection chip is located above the glass substrate. The isolation layer is disposed on a surface of the detection chip opposite to the glass substrate. The plurality of redistribution layers is disposed on the isolation layer and spaced from each other, and having a plurality of conductive units. The plurality of conductive contacts is respectively disposed on the plurality of conductive units. The light sheltering layer is disposed on a lateral surface of the chip scale package assembly, and adapted to block light transmission and provide a covering protection function.

According to the claimed invention, the chip scale package assembly includes a chip scale package detector, and the light sheltering layer is attached to a lateral surface of the glass substrate. The chip scale package assembly further includes a wafer level lens, and the light sheltering layer is attached to the lateral surface of the glass substrate and a lateral surface of the wafer level lens.

According to the claimed invention, an imaging area of the detection chip faces the glass substrate, the isolation layer is located on the surface of the detection chip opposite to the imaging area, a part of the plurality of redistribution layers stretches to the other surface of the detection chip whereon the imaging area is located, the optical detection module further comprises a protection layer disposed on the plurality of redistribution layers to expose the plurality of conductive units, and is filled between two adjacent redistribution layers of the plurality of redistribution layers to connect the isolation layer.

According to the claimed invention, a vertical height of the light sheltering layer is equal to or greater than a thickness of the glass substrate of the chip scale package assembly, or a vertical height of the light sheltering layer is equal to or greater than a distance between the glass substrate and the plurality of conductive units.

According to the claimed invention, the detection chip is glued to the glass substrate via an adhesion layer, and the light sheltering layer covers lateral surfaces of the glass substrate and the adhesion layer, or the light sheltering layer covers lateral surfaces of the glass substrate, the adhesion layer and the protection layer.

According to the claimed invention, a thickness of the light sheltering layer is ranged between 5˜500 micrometers, and an optical density of the light sheltering layer is ranged between 1˜5.

The present invention can utilize the finished chip scale package assemblies or the semi-finished chip scale package assemblies to manufacture the optical detection module. The first embodiment can dispose the finished chip scale package assemblies on the carrier, and fill the light sheltering material into the gap between the carrier and the adjacent chip scale package assemblies; then, the carrier is removed and the light sheltering material is trimmed in the middle, so that the light sheltering layer with the predefined thickness and the coverage degree can be formed on the lateral surface of the glass substrate on each of the chip scale package assemblies. The second embodiment can dispose the semi-finished chip scale package assemblies (which do not have the conductive contacts) on the carrier, and cover the sheltering layer on the conductive units of the semi-finished chip scale package assemblies for protection, and fill the light sheltering material into the gap between the carrier and the adjacent chip scale package assemblies; the filling height of the light sheltering material may be arbitrary due to protection of the sheltering layer. The conductive units can be exposed by removing the sheltering layer, for easy installation of the conductive contacts. Then, the carrier is removed and the light sheltering material is trimmed in the middle, so that the light sheltering layer with the predefined thickness and the coverage degree can be formed on the lateral surface of the glass substrate on each of the chip scale package assemblies. One possible embodiment can dispose the chip scale package assembly that includes the chip scale package detector and the wafer level lens on the carrier, and the light sheltering material is filled into the gap and then trimmed in the middle, so as to simultaneously attach the light sheltering layer with the predefined thickness and the coverage degree to the lateral surface of the chip scale package detector and the wafer level lens. Another possible embodiment can dispose the wafer level lens on the carrier, and the light sheltering material is filled into the gap and then trimmed in the middle, so as to attach the light sheltering layer to the lateral surface of the wafer level lens; the foresaid wafer level lens can be assembled with the chip scale package detector having the light sheltering layer illustrated in the first embodiment or the second embodiment for forming the optical detection module.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a sectional view of an optical detection module according to a first embodiment of the present invention.

FIG. 2 is a sectional view of an optical detection module according to a second embodiment of the present invention.

FIG. 3 is a flow chart of a manufacturing method applied for the chip scale package technology according to the first embodiment of the present invention.

FIG. 4 to FIG. 7 are diagrams of the optical detection module in different operation modes according to the first embodiment of the present invention.

FIG. 8 is a flow chart of the manufacturing method applied for the chip scale package technology according to the second embodiment of the present invention.

FIG. 9 to FIG. 12 are diagrams of the optical detection module in different operation modes according to the second embodiment of the present invention.

FIG. 13 to FIG. 16 are diagrams of the chip scale package assembly and the related optical detection module in different operation modes according to another embodiment of the present invention.

FIG. 17 to FIG. 20 are diagrams of the chip scale package assembly in different operation modes according to another embodiment of the present invention.

### DETAILED DESCRIPTION

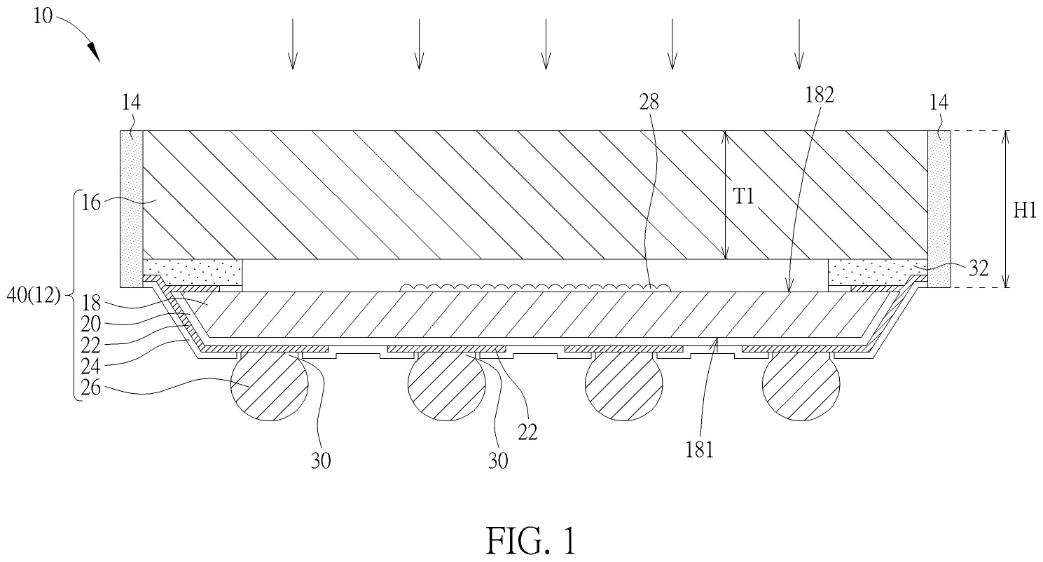

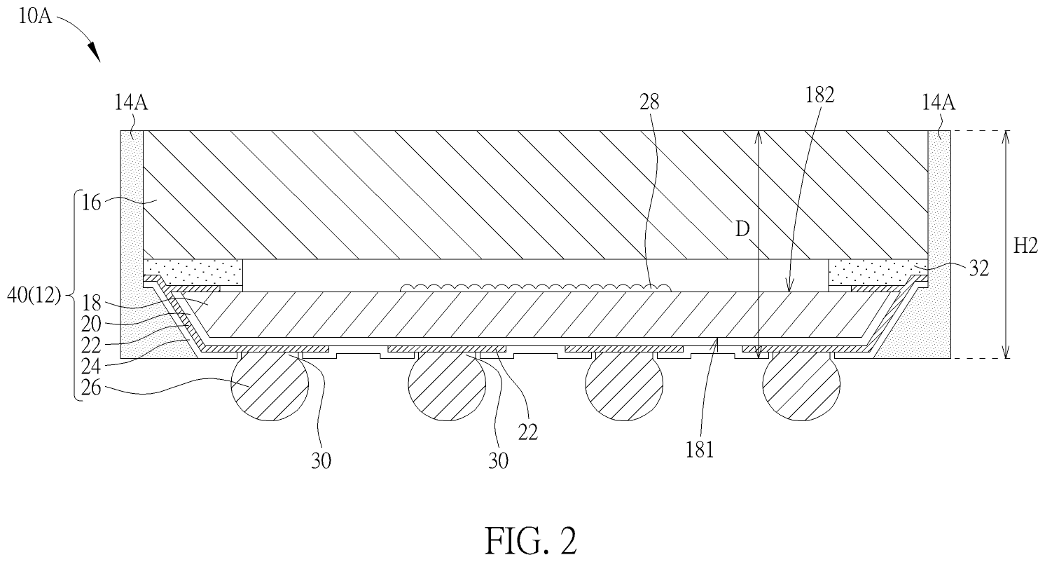

Please refer to FIG. 1 and FIG. 2. FIG. 1 is a sectional view of an optical detection module 10 according to a first embodiment of the present invention. FIG. 2 is a sectional view of an optical detection module 10A according to a second embodiment of the present invention. The optical detection module 10 and the optical detection module 10A can be the CMOS (Complementary Metal-Oxide-Semiconductor) image sensor made by chip scale package technology, and a type of the image sensor is not limited to the foresaid embodiment, and can depend on an actual demand. In the second embodiment, elements having the same numerals as ones of the first embodiment have the same structures and functions, and a detailed description is omitted herein for simplicity.

The optical detection module 10 can include a chip scale package assembly 12 and a light sheltering layer 14; in the first embodiment and the second embodiment, the chip scale package assembly 12 can be defined as a chip scale package detector 40, and application of the chip scale package assembly 12 is not limited to the foresaid embodiment. A vertical height H1 of the light sheltering layer 14 is short than an overall height of the chip scale package assembly 12, and the vertical height H1 that is the same as or slightly greater than a thickness of a glass substrate 16 of the chip scale package assembly 12 can conform to a design scope of the present invention. The optical detection module 10A can include the chip scale package assembly 12 and the light sheltering layer 14A; a vertical height H2 of the light sheltering layer 14A can be greater than the thickness of the glass substrate 16 of the chip scale package assembly 12, and a part of the light sheltering layer 14A may be partly overlapped with a detection chip 18 of the chip scale package assembly 12.

The optical detection module 10 of the first embodiment can utilize the light sheltering layer 14 to block a lateral surface of the glass substrate 16, so as to avoid light leakage and the chip scale package assembly 12 can have preferred detection efficiency. The optical detection module 10A of the second embodiment can dispose the light sheltering layer 14A on position of sheltering the lateral surfaces of the glass substrate 16 and the detection chip 18, and therefore the chip scale package assembly 12 can have the preferred detection efficiency. The thickness of the light sheltering layer 14 (or the light sheltering layer 14A) can be varied in accordance with the demanded material properties, such as an optical density (which can be interpreted as a logarithm of a ratio of an incident beam to a transmitted beam). The present invention can choose the light sheltering layer 14 (or the light sheltering layer 14A) having material property capable of being uniformly coated, and a coverage degree of the light sheltering layer 14 (or the light sheltering layer 14A) relative to the chip scale package assembly 12 can be accurately decided. Parameters of the light sheltering layer 14 (or the light sheltering layer 14A), such as the material, the thickness, and the optical density, can depend on the design demand, and the detailed description is omitted herein for simplicity.

In the present invention, the chip scale package assembly 12 can include the glass substrate 16, the detection chip 18, an isolation layer 20, a redistribution layer 22, a protection layer 24 and a conductive contact 26. The detection chip 18 can be consisted of a silicon substrate and related etched circuits (which are not shown in the figures), and can be disposed on the glass substrate 16. An imaging area 28 of the detection chip 18 can face toward the glass substrate 16. The isolation layer 20 can be disposed on a surface 181 of the detection chip 18 opposite to the glass substrate 16, or can be interpreted as on the surface 181 of the detection chip 18 opposite to the imaging area 28. A plurality of redistribution layers 22 can be disposed on the isolation layer 20 and spaced from each other, and each of the plurality of redistribution layers 22 can have a corresponding conductive unit 30. Some of the plurality of redistribution layers 22 can be optionally stretched toward the other surface 182 of the detection chip 18 where on the imaging area 28 is located. The protection layer 24 can cover the plurality of redistribution layers 22 to expose a plurality of conductive units 30, and be filled between two adjacent redistribution layers 22 to connect with the isolation layer 20.

The redistribution layer 22 can be made of conductive material, and the protection layer 24 can be made of insulation material used to cover the redistribution layer 22 and to avoid the adjacent conductive units 30 from electrical conduction. The plurality of conductive contacts 26 can be respectively disposed on the corresponding conductive units 30, for being external contacts of the optical detection module 10. It should be mentioned that the detection chip 18 may be glued to the glass substrate 16 via an adhesion layer 32, and a gap between the detection chip 18 and the adhesion layer 32 can be filled by thermosetting epoxy compound or similar polymer, such as epoxy resins. Composition of the chip scale package assembly 12 is not limited to the foresaid embodiments, and depends on the design demand. The incident beam can pass through the glass substrate 16 in an arrow direction, and be received and analyzed by the imaging area 28 of the detection chip 18. A chamber may be formed between the glass substrate 16 and the detection chip 18, and a size of the chamber can depend on the design demand.

In the first embodiment, the vertical height H1 of the light sheltering layer 14 cannot be smaller than the thickness T of the glass substrate 16, otherwise the optical detection module 10 (or the optical detection module 10A) may have a drawback of the light leakage, so that the vertical height H1 can be the same as or greater than the thickness T; as shown in FIG. 1, the light sheltering layer 14 can cover the lateral surfaces of the glass substrate 16 and the adhesion layer 32, so as to define the thickness and the coverage degree of the light sheltering layer 14 for preventing the light leakage. In the second embodiment, the vertical height H2 of the light sheltering layer 14A can be the same as or greater than a distance D between the glass substrate 16 and the conductive contact 26 (or the related conductive unit 30); as shown in FIG. 2, the light sheltering layer 14A can cover the lateral surfaces of the glass substrate 16, the adhesion layer 32 and the protection layer 24. The light sheltering layer 14 (or the light sheltering layer 14A) of the present invention can have the thickness of 5˜500 micrometers, and have the optical density ranged between 1˜5. Actual values of the thickness and the optical density of the light sheltering layer 14 (or the light sheltering layer 14A) can depend on the design demand.

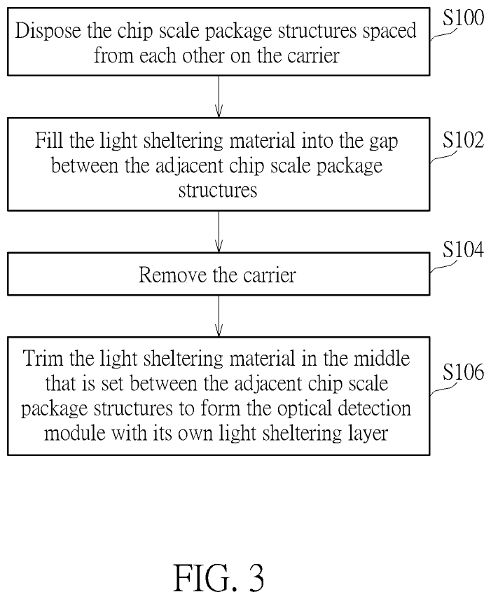

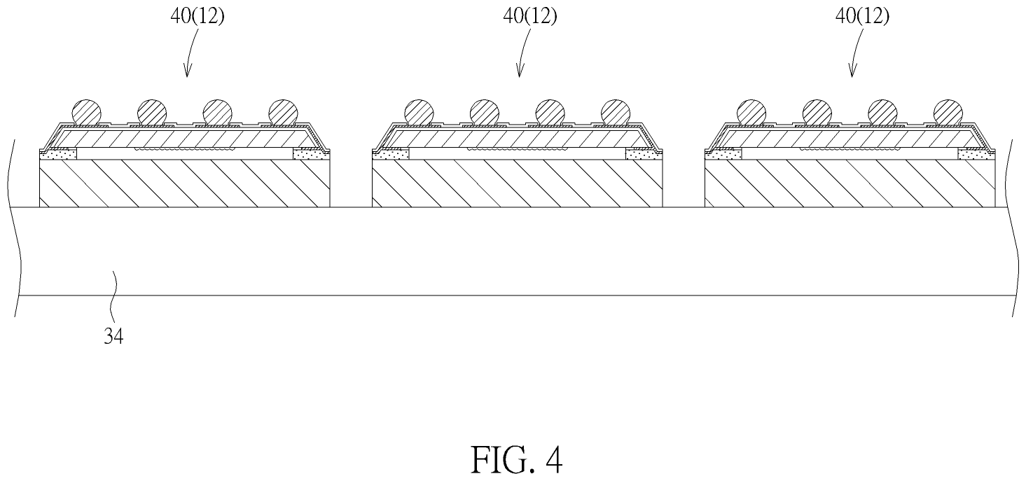

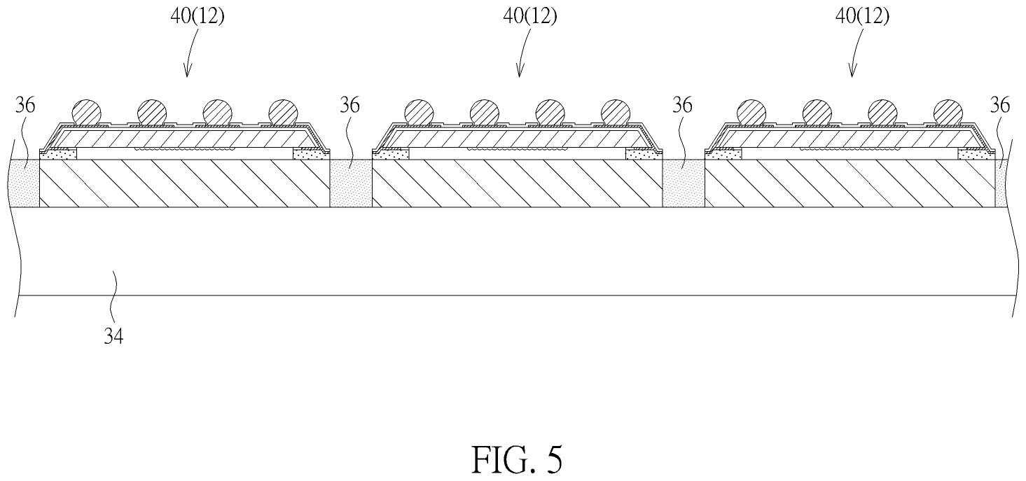

Please refer to FIG. 3 to FIG. 7. FIG. 3 is a flow chart of a manufacturing method applied for the chip scale package technology according to the first embodiment of the present invention. FIG. 4 to FIG. 7 are diagrams of the optical detection module 10 in different operation modes according to the first embodiment of the present invention. The manufacturing method illustrated in FIG. 3 can be suitable for the optical detection module 10 shown in FIG. 1. In the manufacturing method of the first embodiment, when the chip scale package assemblies 12 are acquired, step S100 can be executed to dispose the plurality of chip scale package assemblies 12 spaced from each other on the carrier 34. As shown in FIG. 4, the two adjacent chip scale package assemblies 12 can be spaced from each other on the carrier 34 at the distance of at least or more than 5˜500 micrometers, so that at least one of the cut chip scale package assemblies 12 can include the light sheltering layer 14 having the thickness of 5˜500 micrometers. Then, step S102 can be execute to fill the light sheltering material 36 into the gap between any two adjacent chip scale package assemblies 12. The material properties of the light sheltering material 36 can be the same as the material properties of the light sheltering layer 14. The light sheltering material 36 can be stacked from a bottom of the fore said gap, such as the surface of the carrier 34. A filling height of the sheltering material 36 can be the same as or greater than the thickness T of the glass substrate 16, as shown in FIG. 5.

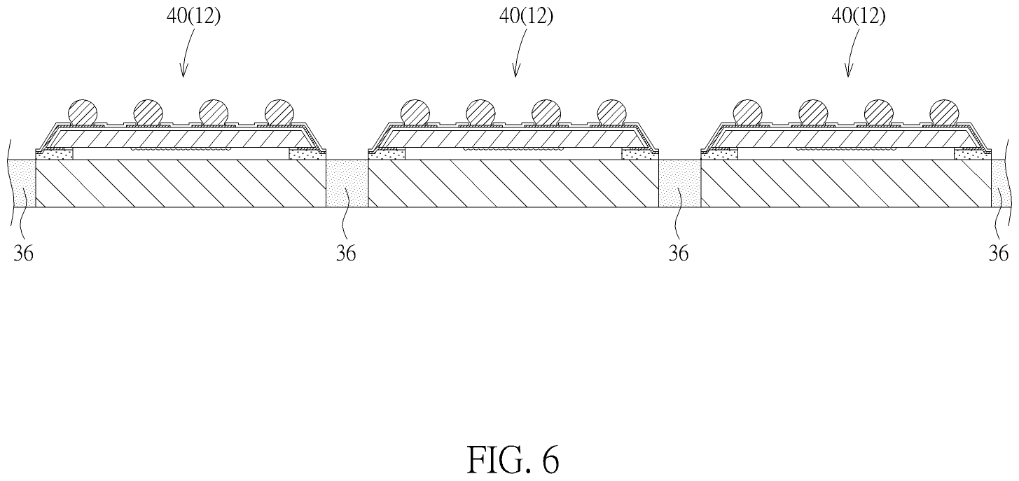

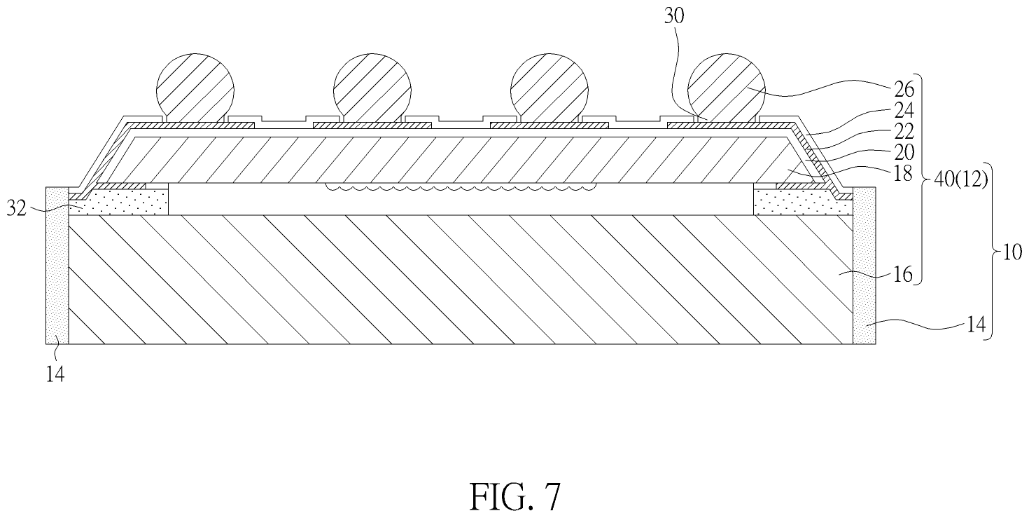

Then, step S104 and step S106 can be executed to remove the carrier 34, and trim the light sheltering material 36 in the middle that is located between the adjacent chip scale package assemblies 12 for separation. The light sheltering material 36 is not limited to be trimmed in the middle, and a trimming position of the light sheltering material 36 can depend on the design demand. Each light sheltering material 36 can be trimmed in the middle to form two light sheltering layers 14 respectively attached to the two adjacent chip scale package assemblies 12. The left side and the right side (or two opposite sides) of the chip scale package assembly 12 can have the light sheltering layer 14, so that each chip scale package assembly 12 with its own light sheltering layers 14 can be set as the optical detection module 10. The carrier 34 can be a substrate for easily filling the light sheltering material 36, and must be removed so that the imaging area 28 of the detection chip 18 can receive an external optical signal, as shown in FIG. 6. The light sheltering material 36 between the adjacent chip scale package assemblies 12 can be trimmed in the middle to form two light sheltering layers 14 respectively applied to the two adjacent chip scale package assemblies 12, as shown in FIG. 7. The light sheltering layer 14 can be located on the lateral surface of the glass substrate 16 on the chip scale package assembly 12, and used to block the beams for protection. The chip scale package assembly 12 having the light sheltering layer 14 can be interpreted as the optical detection module 10. In step S100 and step S106, the distance between the two adjacent chip scale package assemblies 12 on the carrier 34 can be optionally increased; the light sheltering material 36 between the two adjacent chip scale package assemblies 12 that is trimmed in the middle to form two light sheltering layers 14 respectively having the thickness of 5˜500 micrometers can conform to the design scope of the present invention.

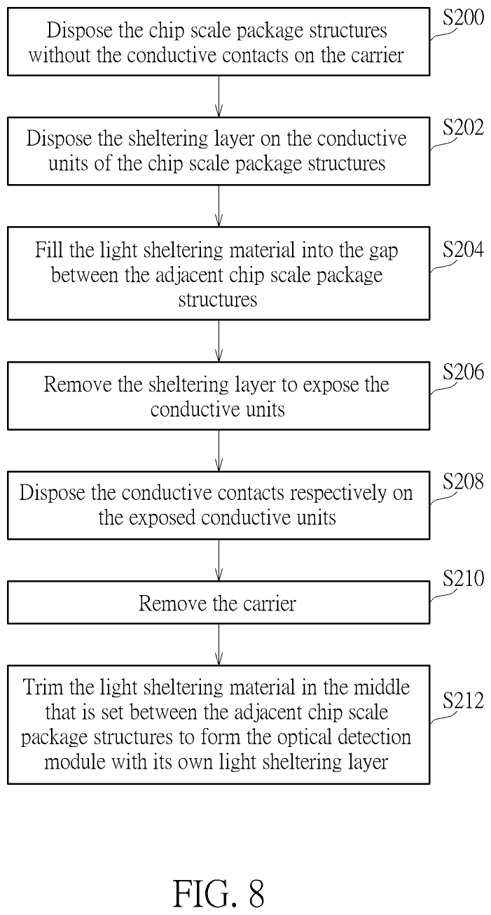

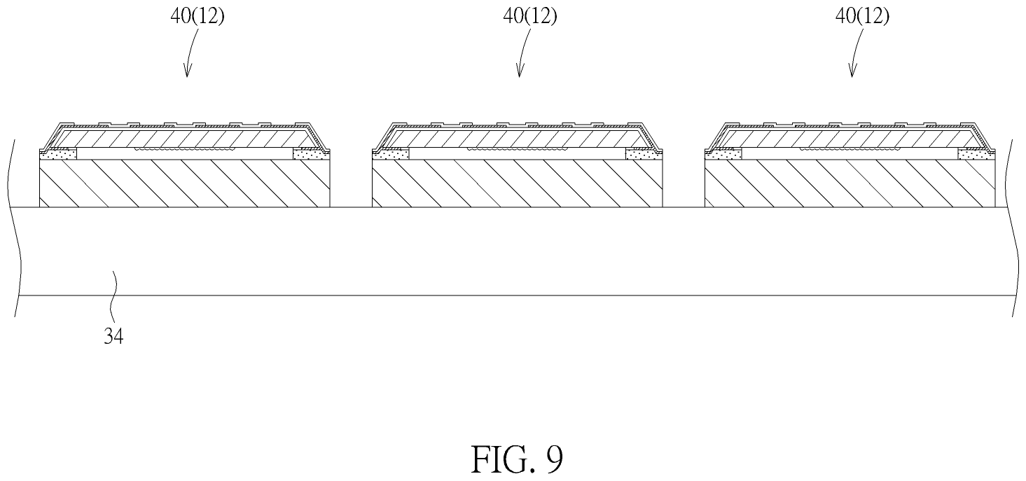

Please refer to FIG. 8 to FIG. 12. FIG. 8 is a flow chart of the manufacturing method applied for the chip scale package technology according to the second embodiment of the present invention. FIG. 9 to FIG. 12 are diagrams of the optical detection module 10A in different operation modes according to the second embodiment of the present invention. The manufacturing method illustrated in FIG. 8 can be suitable for the optical detection module 10A shown in FIG. 2. In the manufacturing method of the second embodiment, when the chip scale package assemblies 12 that does not have the conductive contacts 26 are acquired, step S200 can be executed to dispose the plurality of chip scale package assemblies 12 without the conductive contacts 26 spaced from each other on the carrier 34. As shown in FIG. 9, the two adjacent chip scale package assemblies 12 on the carrier 34 can have the distance of 5˜500 micrometers, and therefore at least one of the trimmed chip scale package assemblies 12 can include the light sheltering layer 14A having the thickness of 5˜500 micrometers. Then, step S202 can be executed to dispose the sheltering layer 38 on the conductive units 30 of the plurality of chip scale package assemblies 12. The sheltering layer 38 is made of removable material, and structural parameters of the sheltering layer 38 can depend on the design demand.

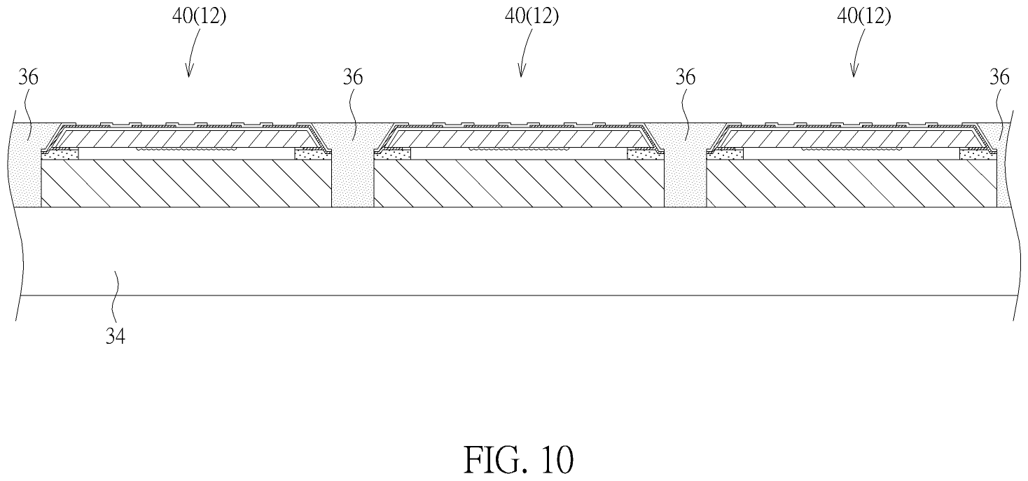

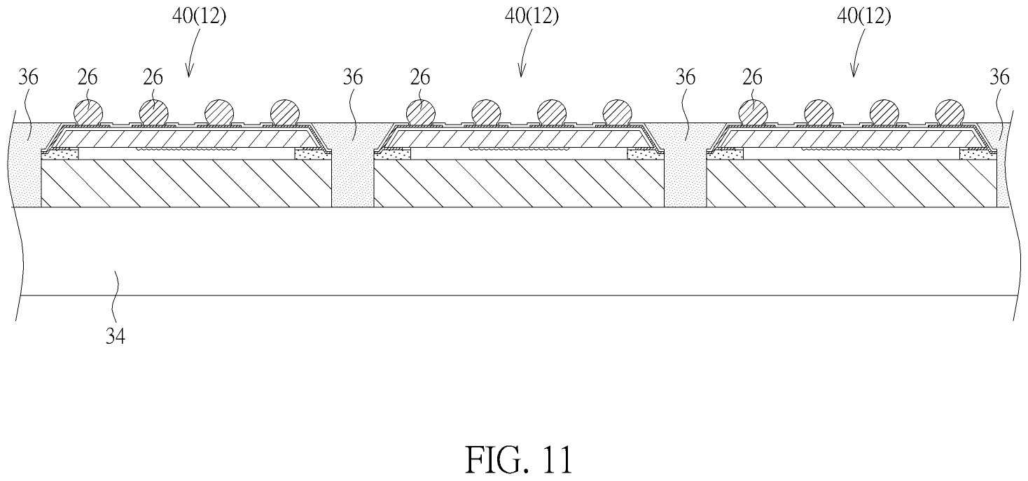

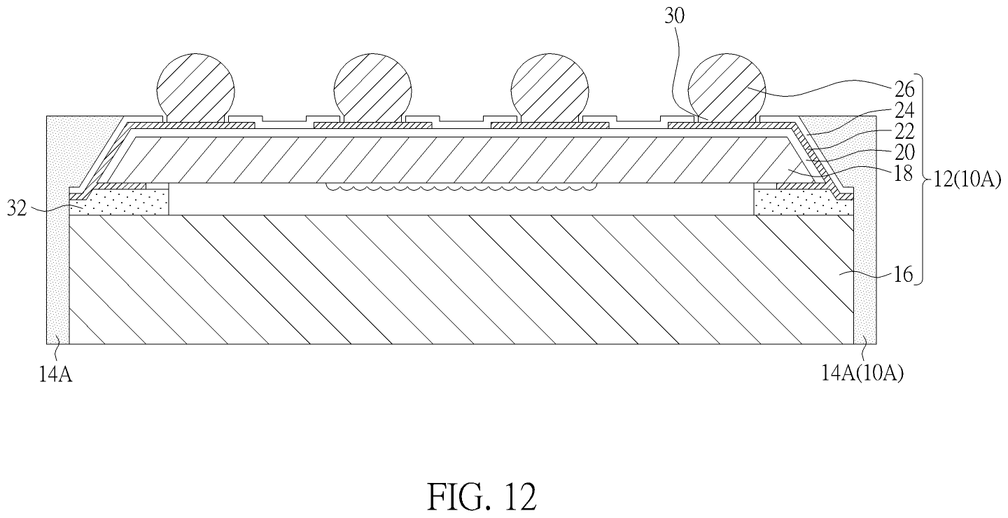

Then, step S204 can be executed to fill the light sheltering material 36 into the gap between any two adjacent chip scale package assemblies 12. As shown in FIG. 10, the material properties of the light sheltering material 36 can be the same as the material properties of the light sheltering layer 14A. The light sheltering material 36 can be stacked from the bottom of the fore said gap, such as the surface of the carrier 34. The filling height of the sheltering material 36 can be the same as or greater than the projection height of the conductive unit 30 (or the related sheltering layer 38) relative to the carrier 34. After that, step S206 and step S208 can be executed to remove the sheltering layer 38 to expose the conductive units 30 (and the light sheltering material 36 coated on the sheltering layer 38 is removed accordingly), and further to dispose the conductive contacts 26 respectively on the exposed conductive units 30. As shown in FIG. 11, the sheltering layer 38 is used to cover and protect the conductive unit 30, and can be easily separated from the conductive units 30 to remove the light sheltering material 36 located above the conductive unit 30. Next, step S210 and step S212 can be executed to remove the carrier 34 and trim the light sheltering material 36 in the middle that is located between the adjacent chip scale package assemblies 12 for separation. The left side and the right side (or two opposite sides) of each of the chip scale package assemblies 12 can have its own light sheltering layer 14A. As shown in FIG. 12, the chip scale package assembly 12 having the light sheltering layer 14A can be interpreted as the optical detection module 10A.

According to the manufacturing process of the chip scale package assembly 12, the silicon substrate that has the detection chips 18 can be adhered to the glass substrate 16 by facing the imaging area 28 toward the glass substrate 16, and the isolation layer 20 can be coated and notched on the surface 181 of the detection chip 18 via lithography etching technology and silicon etching technology; then, the redistribution layer 22 can be formed between the adjacent detection chips 18 via lithography leading technology, and the protection layer 24 can be coated and the conductive contact 26 can be soldered accordingly. After that, the silicon substrate can be cut to separate the chip scale package assemblies 12. Therefore, the first embodiment can combine the finished chip scale package assembly 12 (which has the conductive contact 26) with the light sheltering layer 14 to manufacture the optical detection module 10 in a rapid and easy manner, and the vertical height H1 of the light sheltering layer 14 is preferably the same as or greater than the thickness T of the glass substrate 16. The second embodiment can combine the semi-finished chip scale package assembly (which does not have the conductive contact 26) with the light sheltering layer 14A to manufacture the optical detection module 10A; the filling height of the light sheltering material 36 does not need to align with the edge of the glass substrate 16, and has an advantage of manufacturing convenience.

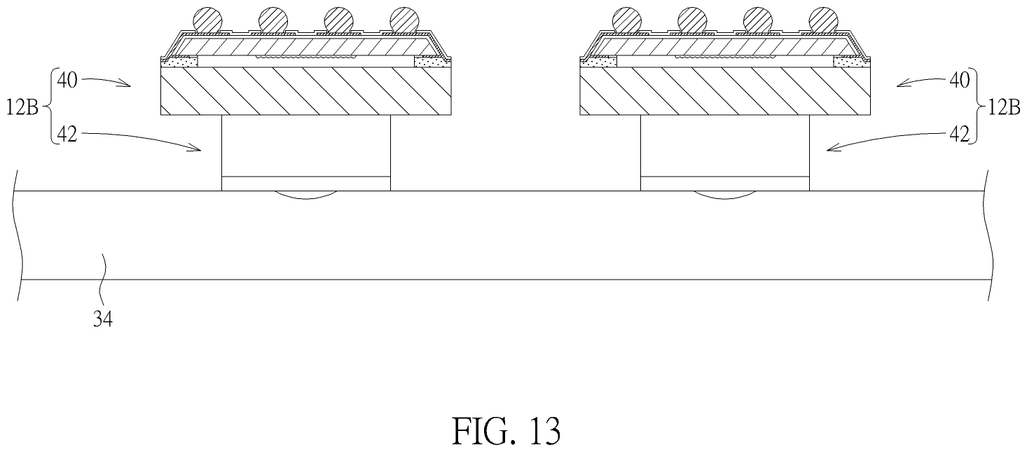

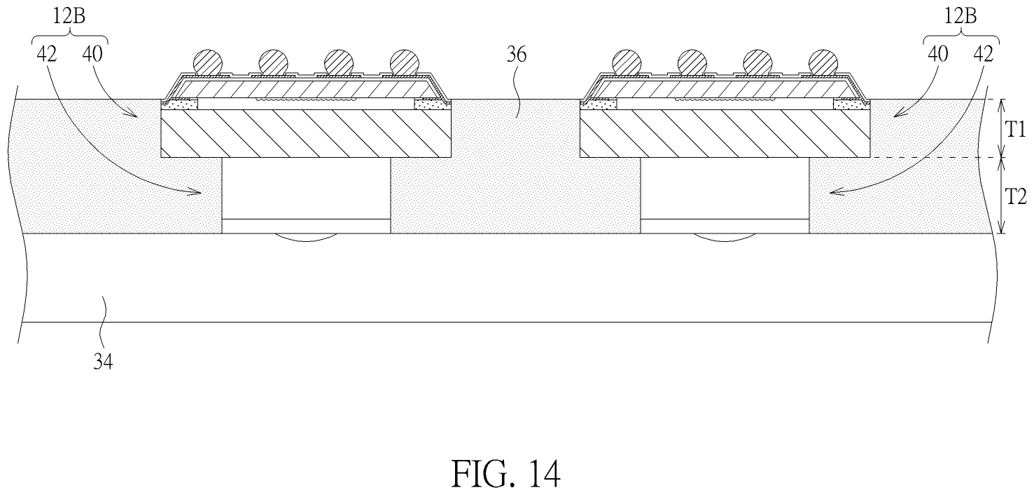

In other possible embodiment, the chip scale package assembly 12B can include the chip scale package detector 40 and a wafer level lens 42. Please refer to FIG. 13 to FIG. 16. FIG. 13 to FIG. 16 are diagrams of the chip scale package assembly 12B and the related optical detection module 10B in different operation modes according to another embodiment of the present invention. First, the chip scale package detector 40 and the wafer level lens 42 are assembled with each other, and then several sets of the chip scale package detector 40 and the wafer level lens 42 (which means a plurality of chip scale package assemblies 12B) are spaced from each other on the carrier 34, as shown in FIG. 13. The two adjacent chip scale package assemblies 12B can be spaced from each other on the carrier 34 at the distance of at least or more than 5˜500 micrometers, so that at least one of the trimmed chip scale package assemblies 12B can include the light sheltering layer 14B having the thickness of 5˜500 micrometers. Then, the light sheltering material 36 can be filled into the gap between any two adjacent chip scale package assemblies 12B. The material properties of the light sheltering material 36 can be the same as the material properties of the light sheltering layer 14B. The light sheltering material 36 can be stacked from a bottom of the fore said gap, such as the surface of the carrier 34. A filling height of the sheltering material 36 can be the same as or greater than a sum of the thickness T1 of the glass substrate 16 and a thickness T2 of the wafer level lens 42, as shown in FIG. 14.

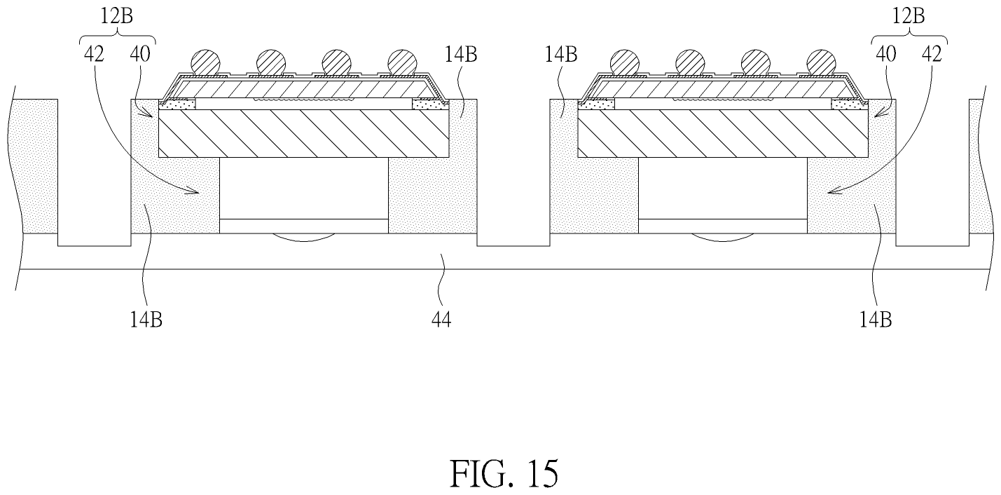

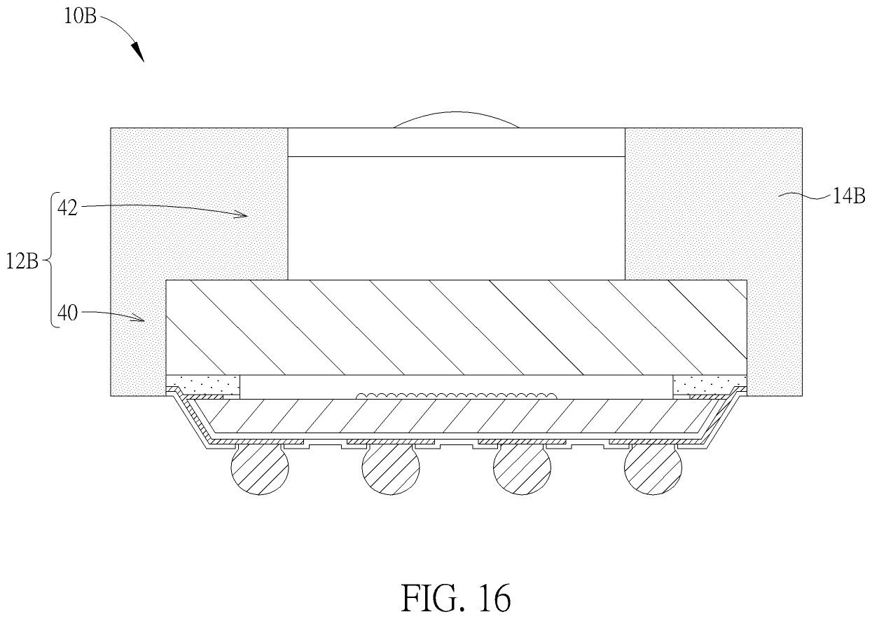

Then, the carrier 34 can be removed, and the chip scale package assemblies 12B and the light sheltering material 36 can be disposed on a UV tape 44, and then the light sheltering material 36 between the adjacent chip scale package assemblies 12B can be trimmed in the middle for separating into two separated chip scale package assemblies 12B. The left side and the right side (or two opposite sides) of the chip scale package assembly 12B can have its own light sheltering layer 14B, as shown in FIG. 15. A purpose of the UV tape 44 is to allow the chip scale package assemblies 12B to be trimmed and separated together when cutting the light sheltering material 36, which means the chip scale package assemblies 12B can be adhered to the UV tape 44 without detachment. A shape of the light sheltering layer 14B can depend on overall structural design of the chip scale package detector 40 and the wafer level lens 42, and is not limited to the embodiment shown in the figures. Final, the UV tape 44 can be removed to acquire the optical detection module 10B that has the light sheltering layer 14B attached to the lateral surface of the glass substrate 16 of the chip scale package detector 40 and the lateral surface of the wafer level lens 42, as shown in FIG. 16.

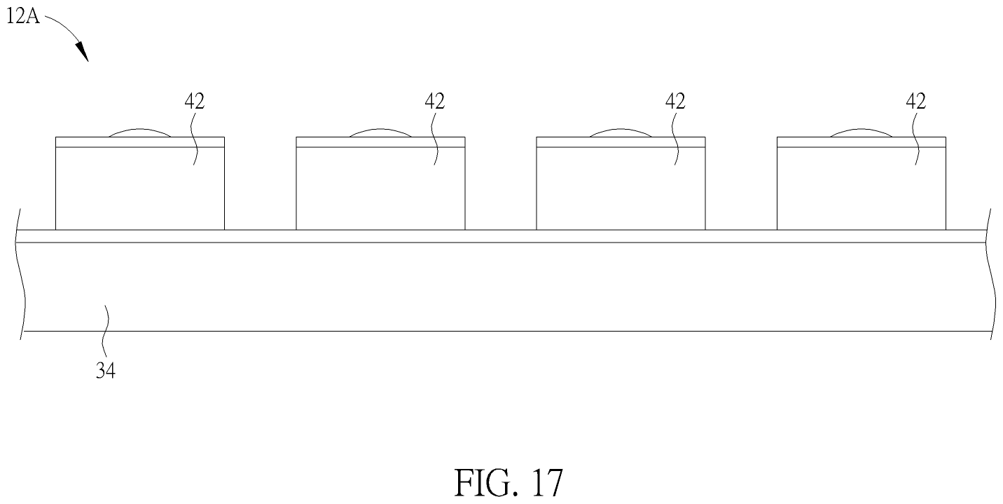

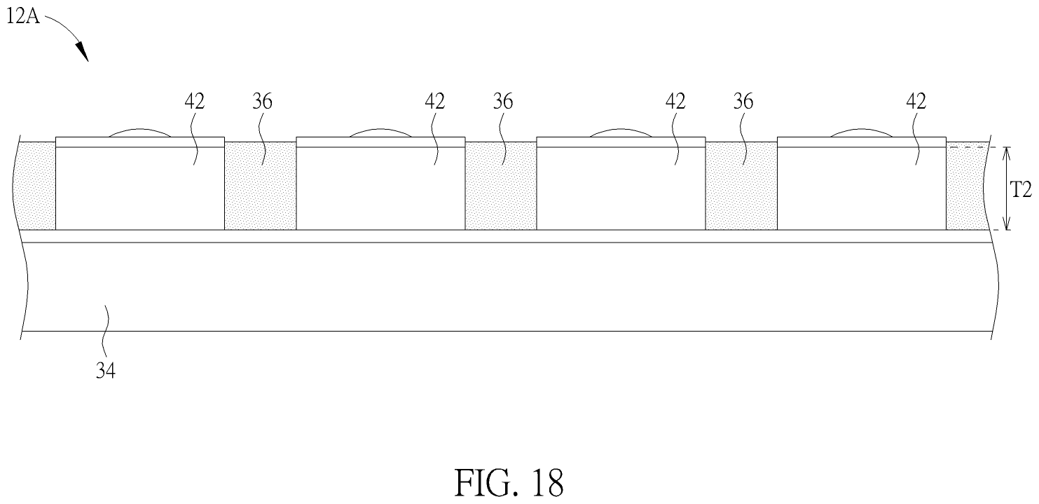

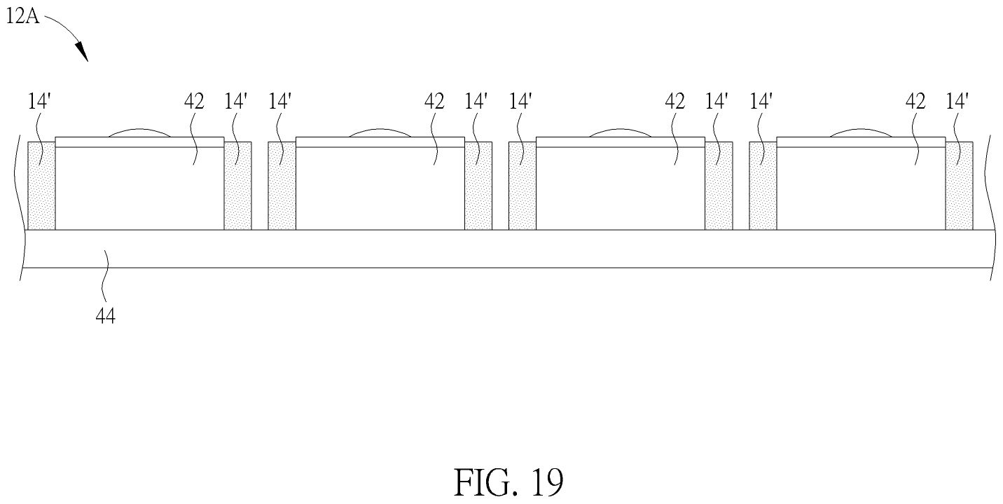

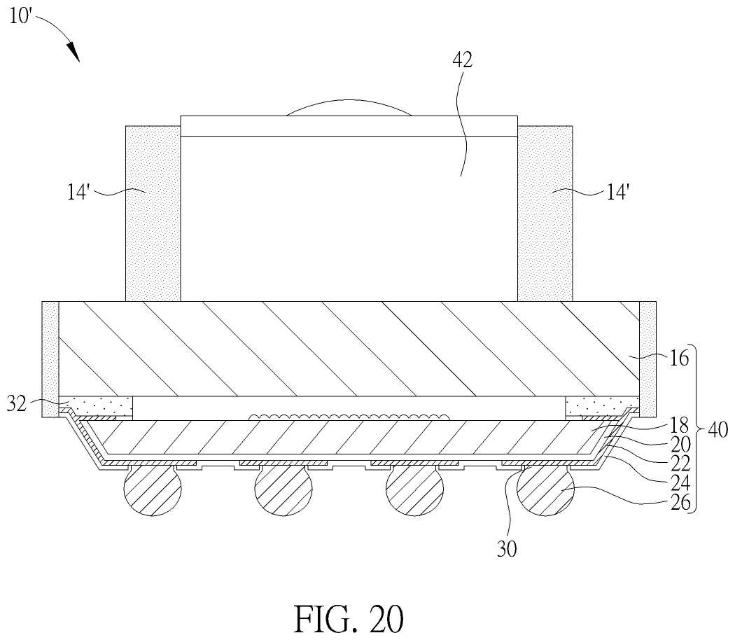

In other possible embodiment, the chip scale package assembly 12A can include the chip scale package detector 40 and the wafer level lens 42; the chip scale package detector 40 is made by the manufacturing method illustrated in the first embodiment or the second embodiment, and the wafer level lens 42 has its own light sheltering layer 14′ and then is assembled with the chip scale package detector 40 having the light sheltering layer 14 or 14A (which means the chip scale package assembly 12 illustrated in the first embodiment or the second embodiment). Please refer to FIG. 17 to FIG. 20. FIG. 17 to FIG. 20 are diagrams of the chip scale package assembly 12A in different operation modes according to another embodiment of the present invention. First, the wafer level lenses 42 are spaced from each other on the carrier 34, as shown in FIG. 17. Then, the light sheltering material 36 can be filled into the gap between any two adjacent wafer level lenses 42. The material properties of the light sheltering material 36 can be the same as the material properties of the light sheltering layer 14′. The light sheltering material 36 can be stacked from a bottom of the fore said gap, such as the surface of the carrier 34. A filling height of the sheltering material 36 can be the same as or greater than the thickness T2 of the wafer level lens 42, as shown in FIG. 18. Then, the carrier 34 can be removed, and the wafer level lenses 42 and the light sheltering material 36 can be disposed on the UV tape 44, and then the light sheltering material 36 between the adjacent wafer level lenses 42 can be trimmed in the middle for separating into two separated wafer level lenses 42. The left side and the right side (or two opposite sides) of the wafer level lens 42 can have its own light sheltering layer 14′, as shown in FIG. 19. Final, the UV tape 44 can be removed to acquire the wafer level lens 42 having the light sheltering layer 14′ attached to the lateral surface, and the foresaid wafer level lens 42 can be assembled with the chip scale package detector 40 having the light sheltering layer 14 or 14A for forming the optical detection module 10′, as shown in FIG. 20.

In conclusion, the present invention can utilize the finished chip scale package assemblies or the semi-finished chip scale package assemblies to manufacture the optical detection module. The first embodiment can dispose the finished chip scale package assemblies on the carrier, and fill the light sheltering material into the gap between the carrier and the adjacent chip scale package assemblies; then, the carrier is removed and the light sheltering material is trimmed in the middle, so that the light sheltering layer with the predefined thickness and the coverage degree can be formed on the lateral surface of the glass substrate on each of the chip scale package assemblies. The second embodiment can dispose the semi-finished chip scale package assemblies (which do not have the conductive contacts) on the carrier, and cover the sheltering layer on the conductive units of the semi-finished chip scale package assemblies for protection, and fill the light sheltering material into the gap between the carrier and the adjacent chip scale package assemblies; the filling height of the light sheltering material may be arbitrary due to protection of the sheltering layer. The conductive units can be exposed by removing the sheltering layer, for easy installation of the conductive contacts. Then, the carrier is removed and the light sheltering material is trimmed in the middle, so that the light sheltering layer with the predefined thickness and the coverage degree can be formed on the lateral surface of the glass substrate on each of the chip scale package assemblies. One possible embodiment can dispose the chip scale package assembly that includes the chip scale package detector and the wafer level lens on the carrier, and the light sheltering material is filled into the gap and then trimmed in the middle, so as to simultaneously attach the light sheltering layer with the predefined thickness and the coverage degree to the lateral surface of the chip scale package detector and the wafer level lens. Another possible embodiment can dispose the wafer level lens on the carrier, and the light sheltering material is filled into the gap and then trimmed in the middle, so as to attach the light sheltering layer to the lateral surface of the wafer level lens; the foresaid wafer level lens can be assembled with the chip scale package detector having the light sheltering layer illustrated in the first embodiment or the second embodiment for forming the optical detection module.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method applied for chip scale package technology, the manufacturing method comprising:
disposing a plurality of chip scale package assemblies spaced from each other on a carrier;
filling light sheltering material into a gap formed between two adjacent chip scale package assemblies of the plurality of chip scale package assemblies;
removing the carrier; and
trimming the light sheltering material in the middle to form two light sheltering layers attached to the two adjacent chip scale package assemblies respectively, so that the two adjacent chip scale package assemblies with its own light sheltering layers respectively are separated to set as two optical detection modules.

2. The manufacturing method of claim 1, wherein the chip scale package assembly comprises a chip scale package detector, and each of the two light sheltering layers is attached to a lateral surface of a glass substrate of each of two adjacent chip scale package detectors.

3. The manufacturing method of claim 2, further comprising:
attaching the light sheltering layer to a lateral surface of a wafer level lens; and
assembling the wafer level lens having the light sheltering layer with the chip scale package detector.

4. The manufacturing method of claim 1, wherein the chip scale package assembly comprises a chip scale package detector and a wafer level lens, the light sheltering layer is attached to a lateral surface of a glass substrate of each of two adjacent chip scale package detectors, and further attached to a lateral surface of each of two adjacent wafer level lenses.

5. The manufacturing method of claim 1, further comprising:
arranging the plurality of chip scale package assemblies on the carrier at a distance of 5˜500 micrometers from each other.

6. The manufacturing method of claim 1, further comprising:
filling the light sheltering material between the glass substrates of the two adjacent chip scale package assemblies, wherein a filling height of the light sheltering material is equal to or greater than as a thickness of the glass substrate of the chip scale package assembly.

7. The manufacturing method of claim 1, further comprising:
trimming the light sheltering material in the middle that is set between the two adjacent chip scale package assemblies to form the two light sheltering layers respectively having a thickness of 5˜500 micrometers.

8. The manufacturing method of claim 1, wherein an optical density of the light sheltering layer of the optical detection module is ranged between 1˜5.

9. A manufacturing method applied for chip scale package technology, the manufacturing method comprising:
disposing a plurality of chip scale package assemblies without conductive contacts spaced from each other on a carrier;
disposing a sheltering layer on conductive units of the plurality of chip scale package assemblies;
filling light sheltering material into a gap formed between two adjacent chip scale package assemblies of the plurality of chip scale package assemblies;
removing the sheltering layer to dispose the conductive contacts respectively on the conductive units;
removing the carrier; and
trimming the light sheltering material in the middle to form two light sheltering layers attached to the two adjacent chip scale package assemblies respectively, so that the two adjacent chip scale package assemblies with its own light sheltering layers respectively are separated to set as two optical detection modules.

10. The manufacturing method of claim 9, wherein the chip scale package assembly comprises a chip scale package detector, and each of the two light sheltering layers is attached to a lateral surface of a glass substrate of each of two adjacent chip scale package detectors.

11. The manufacturing method of claim 10, further comprising:
attaching the light sheltering layer to a lateral surface of a wafer level lens; and
assembling the wafer level lens having the light sheltering layer with the chip scale package detector.

12. The manufacturing method of claim 9, wherein the chip scale package assembly comprises a chip scale package detector and a wafer level lens, the light sheltering layer is attached to a lateral surface of a glass substrate of each of two adjacent chip scale package detectors, and further attached to a lateral surface of each of two adjacent wafer level lenses.

13. The manufacturing method of claim 9, further comprising:
arranging the plurality of chip scale package assemblies on the carrier at a distance of 5˜500 micrometers from each other.

14. The manufacturing method of claim 9, further comprising:
filling the light sheltering material between glass substrates of the two adjacent chip scale package assemblies, wherein a filling height of the light sheltering material is equal to or greater than a projection height of the conductive units relative to the carrier.

15. The manufacturing method of claim 9, further comprising:
trimming the light sheltering material in the middle that is set between the two adjacent chip scale package assemblies to form the two light sheltering layers respectively having a thickness of 5˜500 micrometers.

16. The manufacturing method of claim 9, wherein an optical density of the light sheltering layer of the optical detection module is ranged between 1˜5.

17. An optical detection module applied for chip scale package technology, comprising:
a chip scale package assembly, comprising:
a glass substrate;
a detection chip located above the glass substrate;
an isolation layer disposed on a surface of the detection chip opposite to the glass substrate;
a plurality of redistribution layers disposed on the isolation layer and spaced from each other, and having a plurality of conductive units; and
a plurality of conductive contacts respectively disposed on the plurality of conductive units; and
a light sheltering layer disposed on a lateral surface of the chip scale package assembly, and adapted to block light transmission and provide a covering protection function.

18. The optical detection module of claim 17, wherein the chip scale package assembly comprises a chip scale package detector, and the light sheltering layer is attached to a lateral surface of the glass substrate.

19. The optical detection module of claim 18, wherein the chip scale package assembly further comprises a wafer level lens, and the light sheltering layer is attached to the lateral surface of the glass substrate and a lateral surface of the wafer level lens.

20. The optical detection module of claim 17, wherein an imaging area of the detection chip faces the glass substrate, the isolation layer is located on the surface of the detection chip opposite to the imaging area, a part of the plurality of redistribution layers stretches to the other surface of the detection chip whereon the imaging area is located, the chip scale package assembly further comprises a protection layer disposed on the plurality of redistribution layers to expose the plurality of conductive units, and is filled between two adjacent redistribution layers of the plurality of redistribution layers to connect the isolation layer.

21. The optical detection module of claim 17, wherein a vertical height of the light sheltering layer is equal to or greater than a thickness of the glass substrate of the chip scale package assembly.

22. The optical detection module of claim 17, wherein a vertical height of the light sheltering layer is equal to or greater than a distance between the glass substrate and the plurality of conductive units.

23. The optical detection module of claim 17, wherein the detection chip is glued to the glass substrate via an adhesion layer, the light sheltering layer covers lateral surfaces of the glass substrate and the adhesion layer.

24. The optical detection module of claim 17, wherein the detection chip is glued to the glass substrate via an adhesion layer, the light sheltering layer covers lateral surfaces of the glass substrate, the adhesion layer and the protection layer.

25. The optical detection module of claim 17, wherein a thickness of the light sheltering layer is ranged between 5˜500 micrometers, and an optical density of the light sheltering layer is ranged between 1˜5.
